(19) United States
(12) Patent Application Publication
(10) Pub. No.: US 2014/0174494 A1
(43) Pub. Date: Jun. 26, 2014

(54) THERMOELECTRIC MATERIAL, THERMOELECTRIC ELEMENT AND APPARATUS INCLUDING THE SAME, AND PREPARATION METHOD THEREOF

(71) Applicant: Samsung Electronics Co., Ltd., Suwon-si (KR)

(72) Inventors: Jung-young CHO, Chungcheongnam-do (KR); Sang-il KIM, Seoul (KR); Sung-woo HWANG, Yongin-si (KR); Jong-wook ROH, Yongin-si (KR); Kyu-hyoung LEE, Hwaseong-si (KR)

(73) Assignee: Samsung Electronics Co., Ltd., Suwon-si (KR)

(21) Appl. No.: 14/069,600

(22) Filed: Nov. 1, 2013

(30) Foreign Application Priority Data
Nov. 20, 2012 (KR) 10-2012-0131948

(51) Int. Cl. H01L 35/16; H01L 35/18; H01L 35/28

(52) U.S. Cl. CPC H01L 35/16; H01L 35/28; H01L 35/18
USPC 136/203; 136/238; 136/205; 136/206; 252/519.13; 374/163

(57) ABSTRACT

A thermoelectric material including a compound represented by Formula 1:

MₓBi_{y-a}AₐSe_{z-b}Q_{b} Formula 1

wherein, 1<x<2, 4<y−a<5, 7<z−b<9, 0≦a<5, and 0≦b<9;
M is at least one transition metal element;
A is at least one element of Groups 13 to 15; and
Q is at least one element of Groups 16 to 17.

### CROSS-REFERENCE TO RELATED APPLICATION

This application claims priority to and the benefit of Korean Patent Application No. 10-2012-0131948, filed on Nov. 20, 2012, and all the benefits accruing therefrom under 35 U.S.C. §119, the content of which is incorporated herein in its entirety by reference.

### BACKGROUND

1. Field

The present disclosure relates to a thermoelectric material, and a thermoelectric elements and an apparatus including the thermoelectric material, and preparation methods of the thermoelectric material.

2. Description of the Related Art

The thermoelectric phenomenon refers to a reversible, direct energy conversion between heat and electricity when electrons and holes move in a thermoelectric material.

The thermoelectric phenomena include the Peltier effect, the Seebeck effect, and the Thomson effect. The Peltier effect provides for heat emission or absorption that occurs at a junction between dissimilar materials due to an external current applied to the two dissimilar materials, which are connected to each other by the junction therebetween. The Seebeck effect provides for an electromotive force that is generated due to a temperature difference between opposite ends of the two dissimilar materials which are connected to each other by a junction therebetween, and the Thomson effect provides for heat emission or absorption that occurs when a current flows in a material having a predetermined temperature gradient.

Low temperature waste heat may be converted directly and efficiently into electricity, and vice versa, using the thermoelectric phenomenon. Thus, efficiency of energy utilization may be increased. Also, the thermoelectric material may be applied to a variety of fields, such as a thermoelectric generator or a thermoelectric cooler.

The energy conversion efficiency of the thermoelectric material with the thermoelectric phenomena may be represented by a dimensionless figure of merit ZT defined by Equation 1:

$$Z T = \frac{{S}^{2} σ T}{κ} \qquad Equation 1$$

wherein ZT is a figure of merit, S is a Seebeck coefficient, σ is an electrical conductivity, T is an absolute temperature, and k is a thermal conductivity.

In order to increase the energy conversion efficiency of the thermoelectric material, the thermoelectric material desirably provides a large Seebeck coefficient, a high electrical conductivity, and a low thermal conductivity. The Seebeck coefficient, electrical conductivity, and thermal conductivity have a trade-off relationship. For example, when the lattice thermal conductivity is reduced by defects in a material, the carrier mobility is reduced, and as a result, the electrical conductivity is decreased.

The material having a nano-structure has a smaller particle size than a bulk material. Because of the smaller particle size, a density of grain boundaries is increased, and phonon scattering is accordingly increased at the boundaries of the nano-structure, which results in reduced thermal conductivity. Based on the quantum confinement effect, the trade-off relationship between the Seebeck coefficient and the electrical conductivity may be broken to thereby improve the figure of merit. However, it is difficult to produce the nano-structure in a bulk phase, and when a temperature increases, nano-structures have poor reproducibility.

The thermoelectric material having a complicated crystalline structure has both low thermal conductivity and low electrical conductivity. Thus, the figure of merit is low.

Therefore, an improved thermoelectric material, which is easy to manufacture in a bulk phase and provides an improved figure of merit by having a low thermal conductivity and a high electrical conductivity at the same time, is needed.

### SUMMARY

Provided is a thermoelectric material having a new composition and having low thermal conductivity and high electrical conductivity at the same time.

Provided is a thermoelectric element including the thermoelectric material.

Provided is a thermoelectric module including the thermoelectric element.

Provided are methods of manufacturing the thermoelectric material.

Additional aspects will be set forth in part in the description which follows and, in part, will be apparent from the description.

According to an aspect, a thermoelectric material includes a compound represented by Formula 1:

MₓBi_{y-a}AₐSe_{z-b}Q_{b} Formula 1

wherein, in Formula 1, 1<x<2, 4<y−a<5, 7<z−b<9, 0≦a<5, 0≦b<9;

M is at least one transition metal element;

A is at least one element of Groups 13 to 15; and

Q is at least one element of Groups 16 and 17.

According to another aspect, a thermoelectric element includes the thermoelectric material.

According to another aspect, a thermoelectric module including a first electrode, a second electrode, and the thermoelectric element interposed between the first electrode and the second electrodes.

### BRIEF DESCRIPTION OF THE DRAWINGS

These and/or other aspects will become apparent and more readily appreciated from the following description of the embodiments, taken in conjunction with the accompanying drawings in which:

FIG. 1 is a diagram schematically illustrating a crystalline structure of a compound prepared according to Example 1;

FIG. 2A is a graph of intensity (arbitrary units) versus scattering angle (degrees two-theta) showing an X-ray diffraction (XRD) spectrum obtained by calculation based on the crystalline structure of FIG. 1.

FIG. 2B is a graph of intensity (arbitrary units) versus scattering angle (degrees two-theta) showing an XRD spectrum of a compound prepared according to Example 1;

FIG. 2C is a graph of intensity (arbitrary units) versus scattering angle (degrees two-theta) showing an XRD spectrum of a compound prepared according to Example 2;

FIG. 3A is a graph of electrical conductivity (Siemens per centimeter, S/cm) versus temperature (Kelvin, K) showing electrical conductivities of thermoelectric materials prepared according to Examples 1 and 2;

FIG. 3B is a graph of Seebeck coefficient (microvolts per Kelvin, μV/K) versus temperature (K) showing Seebeck coefficients of thermoelectric materials prepared according to Examples 1 and 2;

FIG. 3C is a graph of power factor (milliWatts per meter-Kelvin², mW/mK²) versus temperature (Kelvin) showing power factors of thermoelectric materials prepared according to Examples 1 and 2;

FIG. 3D is a graph of thermal conductivity (Watts per meter-Kelvin, W/mK) versus temperature (Kelvin) showing thermal conductivities of thermoelectric materials prepared according to Examples 1 and 2;

FIG. 3E is a graph of lattice thermal conductivity (Watts per meter-Kelvin, W/mK) versus temperature (Kelvin) showing lattice thermal conductivities of thermoelectric materials prepared according to Examples 1 and 2;

FIG. 3F is a graph of figure of merit (ZT) versus temperature (Kelvin) showing figure of merits (ZTs) of thermoelectric materials prepared according to Examples 1 and 2;

FIG. 3G is a graph of electrical conductivity (Siemens per centimeter, S/cm) versus temperature (Kelvin, K) showing electrical conductivities of thermoelectric materials prepared according to Examples 8 to 13;

FIG. 3H is a graph of Seebeck coefficient (microvolts per Kelvin, μV/K) versus temperature (K) showing Seebeck coefficients of thermoelectric materials prepared according to Examples 8 to 13;

FIG. 3I is a graph of power factor (milliWatts per meter-Kelvin², mW/mK²) versus temperature (Kelvin) showing power factors of thermoelectric materials prepared according to Examples 8 to 13;

FIG. 3J is a graph of thermal conductivity (Watts per meter-Kelvin, W/mK) versus temperature (Kelvin) showing thermal conductivities of thermoelectric materials prepared according to Examples 8 to 13;

FIG. 3K is a graph of lattice thermal conductivity (Watts per meter-Kelvin, W/mK) versus temperature (Kelvin) showing lattice thermal conductivities of thermoelectric materials prepared according to Examples 8 to 13;

FIG. 3L is a graph of figure of merit (ZT) versus temperature (Kelvin) showing figure of merits (ZTs) of thermoelectric materials prepared according to Examples 8 to 13;

FIG. 4 is a diagram schematically illustrating an embodiment of a thermoelectric module;

FIG. 5 is a diagram schematically illustrating an embodiment of a thermoelectric cooler; and

FIG. 6 is a diagram schematically illustrating an embodiment of a thermoelectric generator.

### DETAILED DESCRIPTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. “Or” means “and/or.” Expressions such as “at least one of,” when preceding a list of elements, modify the entire list of elements and do not modify the individual elements of the list.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

“Transition metal” as defined herein refers to an element of Groups 3 to 12 of the Periodic Table of the Elements.

A thermoelectric material according to an aspect includes a compound represented by Formula 1:

MₓBi_{y-a}AₐSe_{z-b}Q_{b} Formula 1

wherein, 1<x<2, 4<y−a<5, 7<z−b<9, 0≦a<5, and 0≦b<9;

M may be at least one transition metal element;

A may be at least one element of Groups 13 to 15; and

Q may be at least one element of Groups 16 and 17.

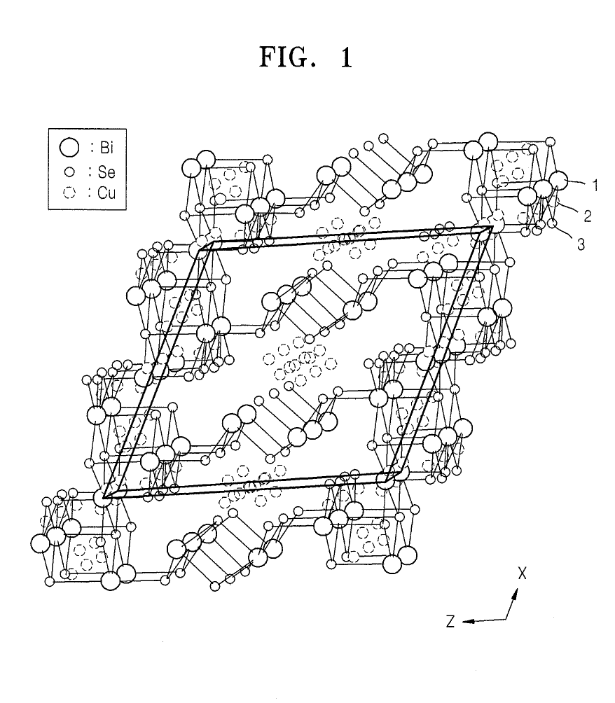

As illustrated in FIG. 1, the compound has a complicated crystalline structure so that photon scattering is efficient. In the structure of FIG. 1, shown are M atoms 2 (e.g., Cu), Bi 1, and Se 3. A atoms of Formula 1 may substitute for Bi, and Q atoms may substitute for Se. Thus, the lattice thermal conductivity may be reduced. The compound may have an improved power factor by optimizing a density of carriers within the above-described composition range. As a result, the compound may have an improved Seebeck coefficient and/or an improved electrical conductivity. Since the compound includes a transition metal, a density of states (“DOS”) of the compound is changed rapidly near the Fermi level, and thus the Seebeck coefficient may be increased. Therefore, figure of merits (ZT) of the thermoelectric materials including the compound may be improved.

In some embodiments, the compound included in the thermoelectric material may be represented by Formula 2:

MₓBi_{y-a}AₐSe_{z-b}Q_{b} Formula 2

wherein, 1.5<x<2, 4.5<y−a<5, 7.5<z−b<8.5, 0≦a<5, and 0≦b<8.5;

M may be at least one of Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, or Hg;

A may be at least one element of Groups 13 to 15; and

Q may be at least one element of Groups 16 to 17.

In some embodiments, the compound included in the thermoelectric material may be represented by Formula 3:

MₓBi_{y-a}AₐSe_{z-b}Q_{b} Formula 3

wherein, 1.6<x<1.8, 4.5<y−a<5, 7.5<z−b<8.5, 0≦a<5, and 0≦b<8.5;

M may be at least one of Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, or Hg;

A may be at least one elements of Groups 13 to 15; and

Q may be at least one element of Groups 16 to 17.

In some embodiments, the compound included in the thermoelectric material may be represented by Formula 4:

MₓBi_{y-a}AₐSe_{z-b}Q_{b} Formula 4

wherein, 1.65<x<1.75, 4.5<y−a<5, 7.5<z−b<8.5, 0≦a<5, and 0≦b<8.5;

M may be at least one of Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, or Hg;

A may be at least one element of Groups 13 to 15; and

Q may be at least one element of Groups 16 to 17.

In Formulas 1 to 4, M may be at least one of Cu or Ag. For example, M may be Cu or may include Cu and Ag at the same time, and a mole rate of Cu:Ag may be in a range from about 99.99:0.001 to about 90:10.

In Formulas 1 to 4, A may be at least one of Al, Si, P, Ga, Ge, As, In, Sn, Sb, Tl, or Pb. For example, A may be at least one of Sb or Sn.

In Formulas 1 to 4, Q may be at least one of S, Cl, Br, Te, I, Po, or At. For example, Q may be at least one of Te or S.

In some embodiments, the compound included in the thermoelectric material may be represented by Formula 5:

MₓBi_{y}Se_{z} Formula 5

wherein, 1.5<x<2, 4.5<y<5, and 7.5<z<8.5; and

M may be at least one of Cu or Ag.

The compound described above may have a monoclinic crystal structure, and more particularly the monoclinic crystal structure belonging to a C2/m space group. A specific crystal structure of the compound is illustrated in FIG. 1.

In addition, the compound may have a single-crystalline structure or a polycrystalline structure, according to a method of manufacturing the compound.

The compound may have an electrical conductivity of about 10 Siemens per centimeter (S/cm) or more at 300 Kelvin (K). For example, the compound may have an electrical conductivity of about 50 S/cm or more at 300 K, or about 100 S/cm or more at 300 K. The compound may provide an improved figure of merit by providing a relatively high electrical conductivity relative to the complicated crystalline structure thereof, with regard to a compound having a complicated crystalline structure with a lower electrical conductivity.

The compound may have a thermal conductivity of about 0.5 Watts per meter-kelvin (W/mK) or less at 300 K. For example, the compound may have thermal conductivity of about 0.45 W/mK or less at 300 K, or about 0.4 W/mK or less at 300 K. Based on the compound having a complicated crystal structure, phonon scattering may be efficient enough to reduce the lattice thermal conductivity.

Therefore, a total thermal conductivity of the compound may be reduced and have a thermal conductivity of about 1 W/mK or less at 300 K. For example, the compound may have a thermal conductivity of about 0.8 W/mK or less at 300 K, or about 0.6 W/mK or less at 300 K.

In addition, the compound, which changes the density of states rapidly near the Fermi level, may have the Seebeck coefficient of an absolute value of about 100 microvolts per Kelvin (μV/K) or more at 300 K. For example, the compound may have the Seebeck coefficient of an absolute value of about 110 μV/K or more at 300 K, or about 120 μV/K or more at 300 K.

The thermoelectric material may be formed into a bulk phase. Since the compound does not require a special nanostructure, it is easy to manufacture the thermoelectric material as a bulk phase.

Also, the thermoelectric material may be sinter or powder. For example, the thermoelectric material may be a sinter obtained by sintering the compound, a powder obtained by grinding ingots, or a powder that is not ground and obtained in a powder form during synthesis thereof.

Likewise, the thermoelectric material may be synthesized in a variety of ways.

For example, the thermoelectric material having a polycrystalline structure may be manufactured by following methods, but is not limited thereto.

(1) A method using an ampoule: the method includes adding a raw material in a quartz pipe or metal ampoule, sealing, and heat-treating the quartz pipe or metal ampoule in vacuum.

(2) An arc melting method: the method includes adding a raw material in a chamber and preparing a sample by melting the raw material by arc discharging in inert gas atmosphere.

(3) A solid state reaction method: the method includes mixing a raw powder, hardening the mixed powder, and heat-treating thereafter or heat treating the mixed powder, processing, and sintering thereafter.

For example, the thermoelectric material having a monocrystalline structure may be manufactured by following methods, but is not limited thereto as long as methods may be used in the art.

(1) A metal flux method: the method includes adding a raw material and an element that provides an environment for the raw material to grow well as crystals at a high temperature in a crucible, and heat-treating the element at a high temperature to grow the crystals.

(2) A Bridgman method: the method includes adding a raw material in a crucible, heating an end portion of the crucible at a high temperature until the raw material is melted, and locally melting the raw material by slowly moving a high-temperature region so the entirety of the raw material may pass through the high-temperature region to grow a crystal.

(3) A zone melting method: the method includes preparing a raw material into a seed rod and a feed rod in a rod form, melting the raw material by locally creating atmosphere of a high temperature, and slowly moving the melted portion upward to grow crystals.

(4) A vapor transport method: the method includes adding a raw material on the bottom of a quartz pipe and heating the bottom of the quartz pipe where a top of the quartz pipe is left to stay at a low temperature so that crystals are grown as the raw material is vaporized to cause a solid state reaction at the low temperature.

The compound having a polycrystalline structure may further perform a densification process. Then, an additional electrical conductivity may be improved by such a densification process.

The densification process may be performed according to following three methods:

(1) A hot press method: the method includes disposing a target powdered compound into a mold having a selected shape, and molding the target powdered compound at a high temperature, for example in a range from about 300° C. to about 800° C., and at a high-pressure, for example, in a range from about 30 megaPascals (MPa) to about 300 MPa.

(2) A spark plasma sintering method: the method includes sintering a target powdered compound in the conditions of high-pressure and high-voltage current. That is, the target powdered compound is sintered in a short period of time at a high-pressure in a range from about 30 MPa to about 300 MPa and at a high-voltage current in a range from about 50 A to about 500 A.

(3) A hot forging method: the method includes extrusion-sintering a target powdered compound at a high temperature, for example, in a range from about 300° C. to about 700° C. during pressure molding.

Due to the densification process, the thermoelectric material may have a density nearly amounting to about 70% to about 100% of a theoretical density. The theoretical density may be calculated by dividing the molecular weight by the atomic volume, and may be evaluated as a lattice constant. In some embodiments, due to the densification process, the thermoelectric material may have a density nearly amounting to about 95% to about 100% of a theoretical density so that a more increased electrical conductivity is available.

A thermoelectric element according to another aspect includes a thermoelectric material having a compound represented by Formulas 1 to 4 as described above. The thermoelectric element may be a p-type thermoelectric element or an n-type thermoelectric element. The thermoelectric element may represent a thermoelectric material formed in a selected shape such as a rectangular parallelepiped shape.

The thermoelectric element may be connected to an electrode, and thus may have a cooling effect due to an applied current. Also, the thermoelectric element may be a component that has an electricity generating effect due to a temperature difference.

A thermoelectric module according to another aspect includes a first electrode, a second electrode, and a thermoelectric element that is represented by Formulas 1 to 4 described above and that is interposed between the first electrode and the second electrode.

For example, when there is a temperature difference between the first electrode and the second electrode in the thermoelectric module, the thermoelectric module is provided to generate a current through the thermoelectric element. In the thermoelectric module, the thermoelectric element includes a thermoelectric material having a three-dimensional nano-structure, and a first end of the thermoelectric element is in contact with the first electrode and a second end of the thermoelectric element is in contact with the second electrode. When a temperature of the first electrode is increased compared to a temperature of the second electrode, or a temperature of the second electrode is decreased compared to a temperature of the first electrode, a current flowing from the first electrode to the second electrode via the thermoelectric element may be generated. When the thermoelectric module is in operation, the first electrode and the second electrode may be electrically connected to each other.

In addition, the thermoelectric module may further include a third electrode along with an additional thermoelectric element interposed between the first electrode and the third electrode.

In some embodiments, the thermoelectric module may include a first electrode, a second electrode, a third electrode, a p-type thermoelectric element having a first end and a second end, and an n-type thermoelectric element having a first end and a second end, wherein the first end of the p-type thermoelectric element is in contact with the first electrode, and the second end of the p-type thermoelectric element is in contact with the third electrode while the first end of the n-type thermoelectric element is in contact with the first electrode, and the second end of the n-type thermoelectric element is in contact with the second electrode. Thus, when the first electrode has a temperature higher than temperatures of the second electrode and the third electrode, a current flowing from the second electrode to the n-type thermoelectric element, to the first electrode via the n-type thermoelectric element, to the p-type nano-structure via the first electrode, and to the third electrode via the n-type electrode may be generated. When the thermoelectric module is in operation, the second electrode and the third electrode may be electrically connected to each other. At least one of the p-type thermoelectric element and the n-type thermoelectric element may include a thermoelectric material having a three-dimensional nano-structure.

The thermoelectric module may further include insulating substrates on which at least one of the first electrode, the second electrode, and optionally the third electrode is disposed.

The insulating substrates may comprise a gallium arsenide (GaAs), sapphire, silicon, PYREX, or quartz. Also, the electrodes may be formed in a variety of ways using aluminum, nickel, gold, or titanium, and may have any suitable size. The electrodes may be patterned by using any patterning method such as a lift-off semiconductor process, a deposition method, or a photolithography method.

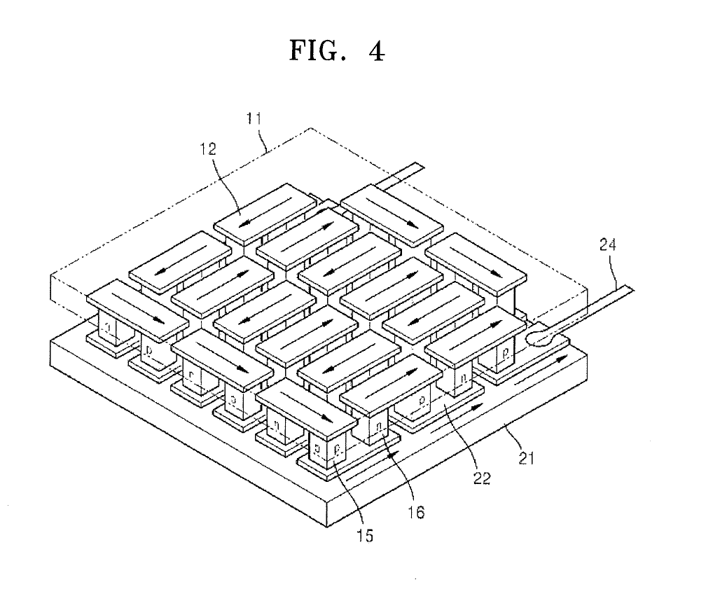

FIG. 4 is a diagram schematically illustrating a thermoelectric module according to an embodiment. As illustrated in FIG. 4, an upper electrode 12 and a lower electrode 22 are patterned respectively on an upper insulating substrate 11 and a lower insulating substrate 21, and a p-type thermoelectric element 15 and an n-type thermoelectric element 16 respectively mutually contacting the upper electrode 12 and the lower electrode 22. The upper and lower electrodes 12 and 22 are connected to the outside of the thermoelectric element via lead electrodes 24.

As illustrated in FIG. 4, the p-type thermoelectric element and the n-type thermoelectric element may be alternately disposed in the thermoelectric module, wherein at least one of the p-type thermoelectric element and the n-type thermoelectric element may include the thermoelectric material having a three-dimensional nano-structure.

One of the first electrode and the second electrode in the thermoelectric module may be electrically connected to a power supply source. A temperature difference between the first electrode and the second electrode may be 1 C or higher, 5° C. or higher, 50° C. or higher, 100° C. or higher, or 200° C. or higher. The temperature of each electrode may be arbitrary selected as long as the temperature does not interfere in dissolution of any component of the thermoelectric module or the current applied thereto.

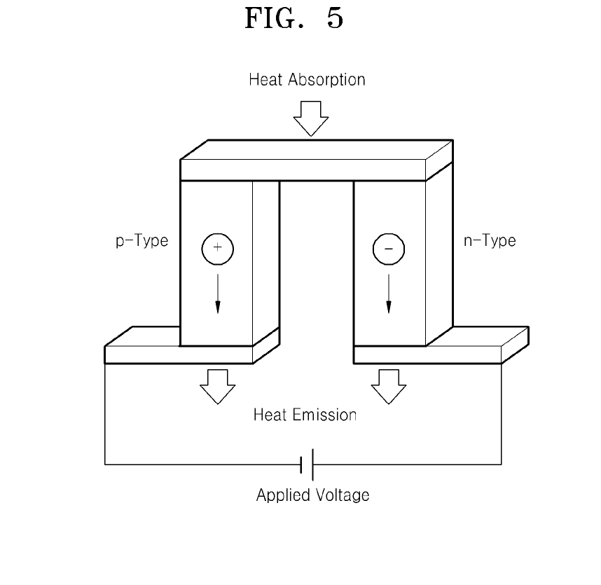

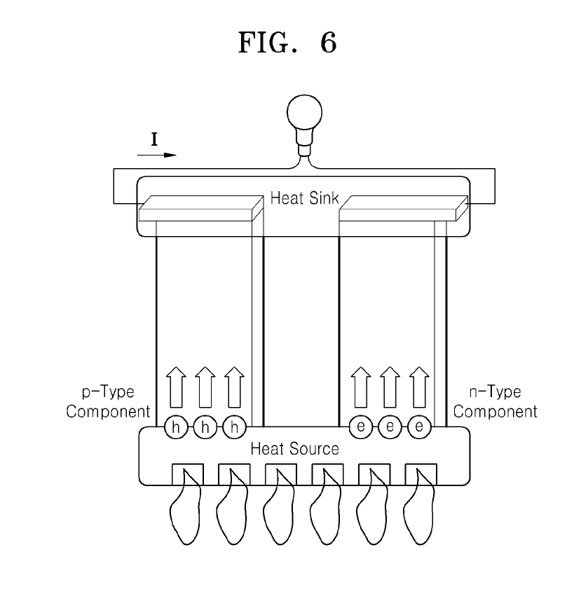

One of the first electrode, the second electrode, and optionally the third electrode in the thermoelectric module may be electrically connected to the power supply source as illustrated in FIG. 5, or to the outside of the thermoelectric module, that is, an electrical device (i.e., a battery) that consumes or stores electric power, as illustrated in FIG. 6.

The thermoelectric module may be included in a thermoelectric apparatus. The thermoelectric apparatus may be a thermoelectric power generator, a thermoelectric cooler, a thermoelectric sensor, a thermoelectric wireless independent power device, a power supply device for a spacecraft, or a solar power generator, but is not limited thereto. Any device that is capable of direct conversion of heat and electricity may be used as a thermoelectric apparatus. A structure and a manufacturing method of the thermoelectric cooling system are well known to one of ordinary skill in the art, and thus, descriptions thereof are omitted.

The present disclosure will be described in greater detail with reference to the following examples. However, the following examples are for illustrative purposes only and are not intended to limit the scope of the invention.

### EXAMPLES

### Preparation of a Thermoelectric Material

### Example 1

### Preparation of a Cu_{1.7}Bi_{4.7}Se₈ Thermoelectric Material

In order to prepare Cu_{1.7}Bi_{4.7}Se₈, Cu, Bi, and Se, which are raw metals, were weighted at a pre-determined composition ratio, put in a quartz tube of diameter 12 mm, and sealed in vacuum under 10⁻³ torr. The sealed quartz tube was then put in a rocking furnace, maintained at a temperature of about 1100° C. for about 10 hours to be melted, and rapidly cooled to prepare a raw material having a polycrystalline structure in an ingot shape. The prepared ingot was ground into powder using a ball mill, and distributed as powder having a size of about 45 μm or less using a mechanical sieve (325 mesh) to obtain initial powder.

A bulk-phase thermoelectric material was prepared by sintering the powder obtained above using a spark plasma sintering method at a temperature of about 480° C. for about 5 minutes under a pressure of 70 MPa and a current of 500 A.

### Example 2

### Preparation of a Cu_{1.717}Bi_{4.7}Se₈ Thermoelectric Material

A thermoelectric material was prepared in the same manner as in Example 1, except that a composition of Cu, Bi, and Se, which are raw metals, was changed to prepare Cu_{1.717}Bi_{4.7}Se₈.

### Example 3

### Preparation of a Cu_{1.6}Ag_{0.1}Bi_{4.7}Se₈ Thermoelectric Material

A thermoelectric material was prepared in the same manner as in Example 1, except that a composition of Cu, Ag, Bi, and Se, which are raw metals, was changed to prepare Cu_{1.6}Ag_{0.1}Bi_{4.7}Se₈.

### Example 4

### Preparation of a Cu_{1.5}Ag_{0.2}Bi_{4.7}Se₈ Thermoelectric Material

A thermoelectric material was prepared in the same manner as in Example 1, except that a composition of Cu, Ag, Bi, and Se, which are raw metals, was changed to prepare Cu_{1.5}Ag_{0.2}Bi_{4.7}Se₈.

### Example 5

### Preparation of a Cu_{1.4}Ag_{0.3}Bi_{4.7}Se₈ Thermoelectric Material

A thermoelectric material was prepared in the same manner as in Example 1, except that a composition of Cu, Ag, Bi, and Se, which are raw metals, was changed to prepare Cu_{1.4}Ag_{0.3}Bi_{4.7}Se₈.

### Example 6

### Preparation of a Cu_{1.7}Bi_{4.8}Se₈ Thermoelectric Material

A thermoelectric material was prepared in the same manner as in Example 1, except that a composition of Cu, Bi, and Se, which are raw metals, was changed to prepare Cu_{1.7}Bi_{4.8}Se₈.

### Example 7

### Preparation of a Cu_{1.7}Bi_{4.7}Se_{7.5} Thermoelectric Material

A thermoelectric material was prepared in the same manner as in Example 1, except that a composition of Cu, Bi, and Se, which are raw metals, was changed to prepare Cu_{1.7}Bi_{4.7}Se_{7.5}.

### Example 8

### Preparation of a Cu_{1.3}Bi_{4.9}Se₈ Thermoelectric Material

In order to prepare Cu_{1.3}Bi_{4.9}Se₈, Cu, Bi, and Se, which are raw metals, were weighted at a pre-determined composition ratio, put in a quartz tube of diameter 12 mm, and sealed in vacuum under 10⁻³ torr. The sealed quartz tube was then put in a rocking furnace, maintained at a temperature of about 1100° C. for about 10 hours to be melted, and rapidly cooled to prepare a raw material having a polycrystalline structure in an ingot shape. The prepared ingot was ground into powder using a ball mill, and distributed as powder having a size of about 45 μm or less using a mechanical sieve (325 mesh) to obtain initial powder.

A bulk-phase thermoelectric material was prepared by sintering the powder obtained above using a spark plasma sintering method at a temperature of about 480° C. for about 5 minutes under a pressure of 70 MPa and a current of 500 A.

### Example 9

### Preparation of a Cu_{1.4}Bi_{4.85}Se₈ Thermoelectric Material

A thermoelectric material was prepared in the same manner as in Example 8, except that a composition of Cu, Bi, and Se, which are raw metals, was changed to prepare Cu_{1.4}Bi_{4.85}Se₈.

### Example 10

### Preparation of a Cu_{1.5}Bi_{4.8}Se₈ Thermoelectric Material

A thermoelectric material was prepared in the same manner as in Example 8, except that a composition of Cu, Ag, Bi, and Se, which are raw metals, was changed to prepare Cu_{1.5}Bi_{4.8}Se₈.

### Example 11

### Preparation of a Cu_{1.6}Bi_{4.75}Se₈ Thermoelectric Material

A thermoelectric material was prepared in the same manner as in Example 8, except that a composition of Cu, Ag, Bi, and Se, which are raw metals, was changed to prepare Cu_{1.6}Bi_{4.75}Se₈.

### Example 12

### Preparation of a Cu_{1.8}Bi_{4.65}Se₈ Thermoelectric Material

A thermoelectric material was prepared in the same manner as in Example 8, except that a composition of Cu, Ag, Bi, and Se, which are raw metals, was changed to prepare Cu_{1.8}Bi_{4.65}Se₈.

### Example 13

### Preparation of a Cu_{1.9}Bi_{4.6}Se₈ Thermoelectric Material

A thermoelectric material was prepared in the same manner as in Example 8, except that a composition of Cu, Bi, and Se, which are raw metals, was changed to prepare Cu_{1.9}Bi_{4.6}Se₈.

### Comparative Example 1

### Preparation of a Bi₂Se₃ Thermoelectric Material

A thermoelectric material was prepared according to the method disclosed in Nano letters, 2012, 12, 1203-1209, the content of which is incorporated herein by reference in its entirety.

The compound obtained above has a hexagonal crystalline structure.

### Comparative Example 2

### Preparation of a Bi₂Te₃ Thermoelectric Material

A thermoelectric material was prepared according to the method disclosed in Nano letters, 2012, 12, 1203-1209.

The compound obtained above has a hexagonal crystalline structure.

### Comparative Example 3

### Preparation of a 0.27(Bi₂Se₃).0.73(Bi₂Te₃) Thermoelectric Material

A thermoelectric material was prepared according to the method disclosed in Nano letters, 2012, 12, 1203-1209.

The compound obtained above has a hexagonal crystalline structure.

### Comparative Example 4

### Preparation of a 0.6(Bi₂Se₃).0.4(Bi₂Te₃) Thermoelectric Material

A thermoelectric material was prepared according to the method disclosed in Nano letters, 2012, 12, 1203-1209.

The compound obtained above has a hexagonal crystalline structure.

### Evaluation Example 1

### XRD Measurement

An X-ray diffraction (XRD) measurement was performed on thermoelectric materials prepared according to Examples 1 and 2, and the results were compared with the XRD spectrum that obtained by calculation based on the assumed crystalline structure of FIG. 1.

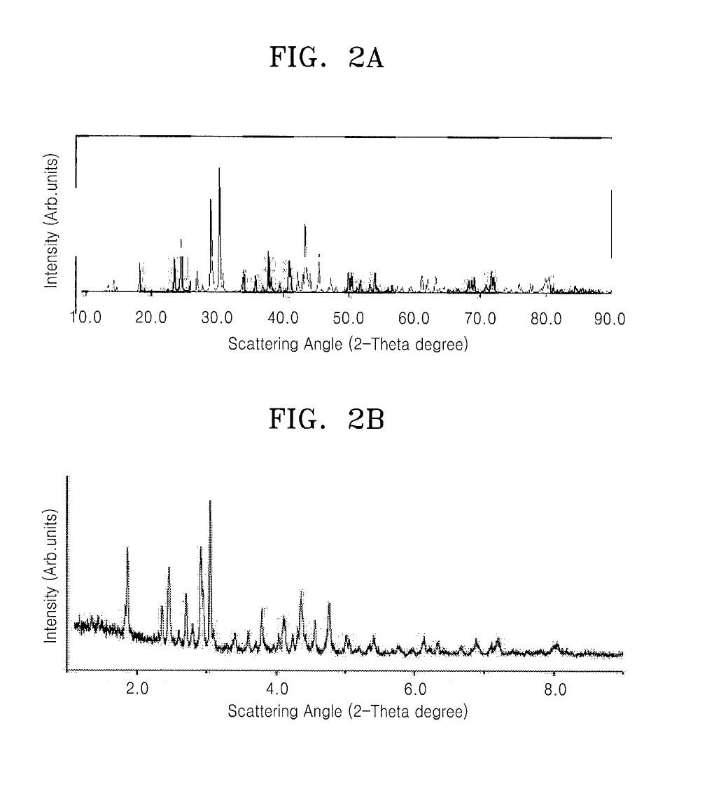

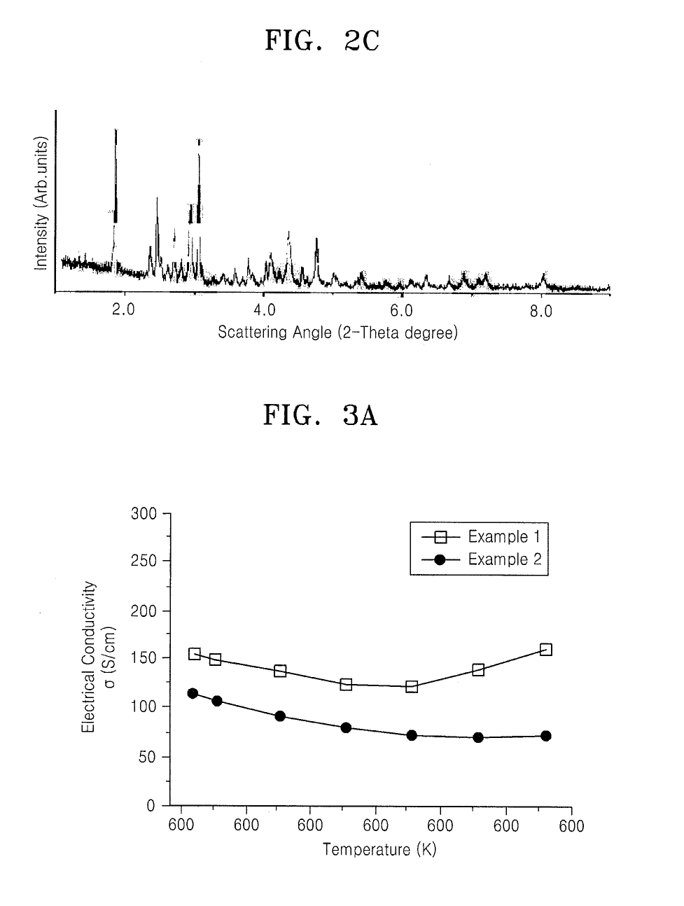

FIG. 2A is a graph showing a calculated XRD spectrum, FIG. 2B is a graph showing an XRD spectrum of a thermoelectric material prepared according to Example 1, and FIG. 2C is a graph showing a XRD spectrum of a thermoelectric material prepared according to Example 2.

As shown in FIGS. 2A to 2C, the XRD spectra of the thermoelectric materials prepared according to Examples 1 and 2 have monoclinic crystalline structures, and are the same with a XRD spectrum that is obtained by assuming a crystalline belonging to C2/m space group.

Therefore, it was confirmed that a thermoelectric material of Examples above has a crystalline structure of FIG. 1.

### Evaluation Example 2

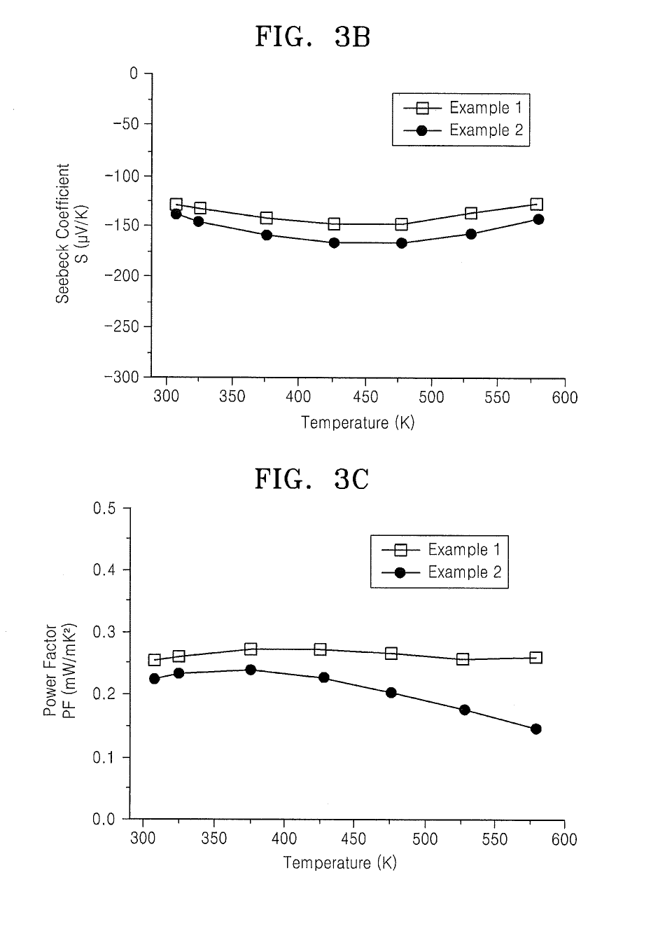

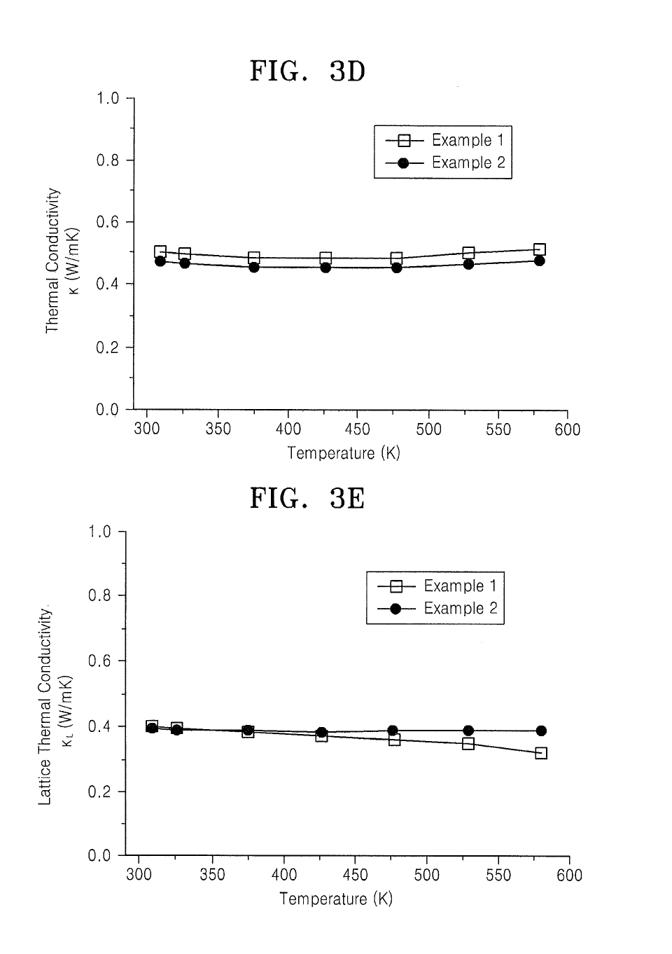

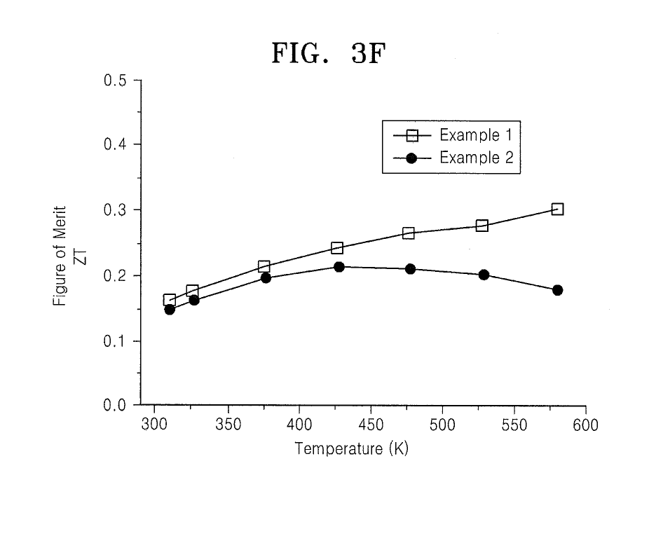

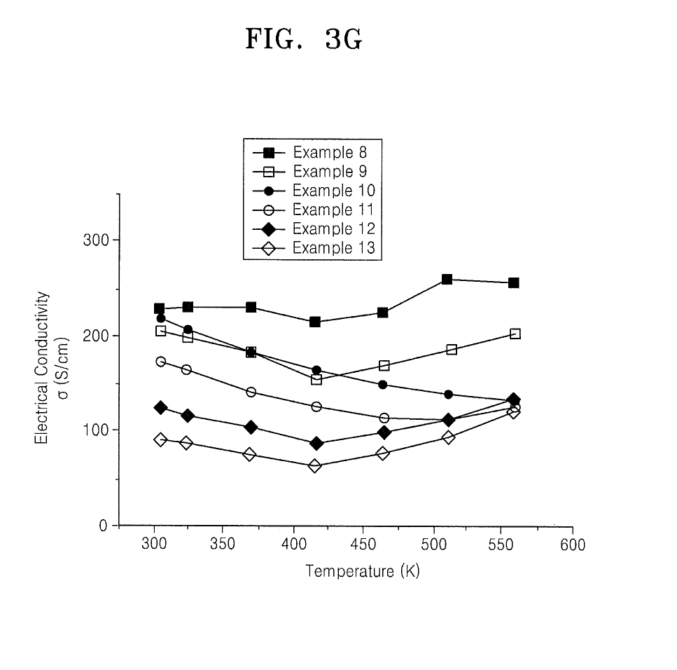

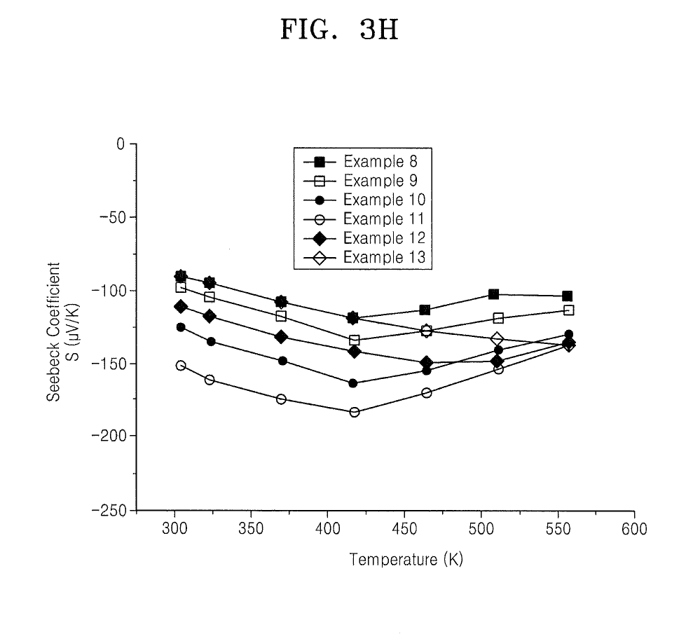

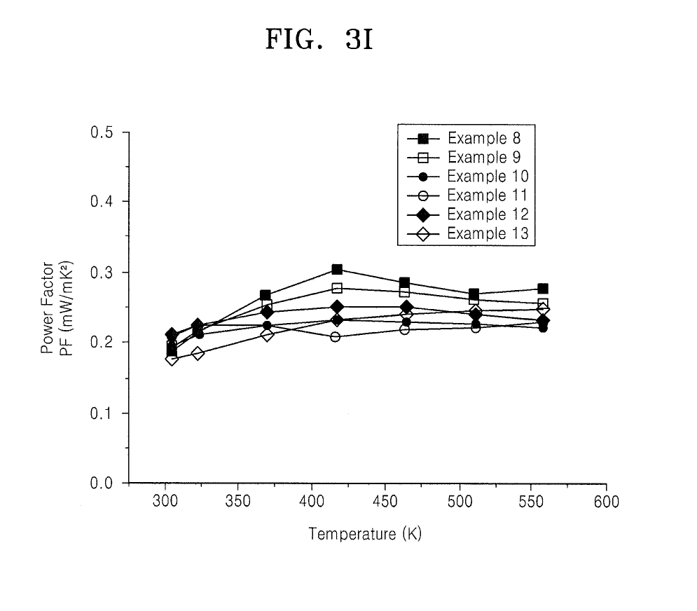

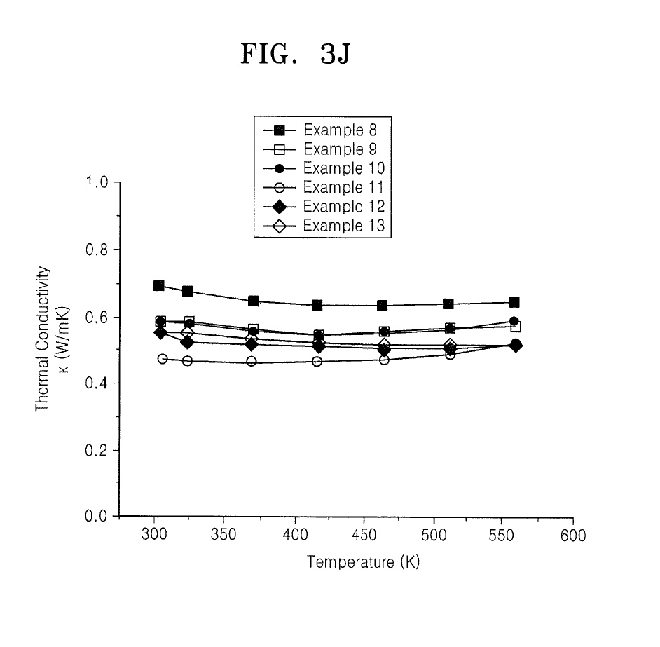

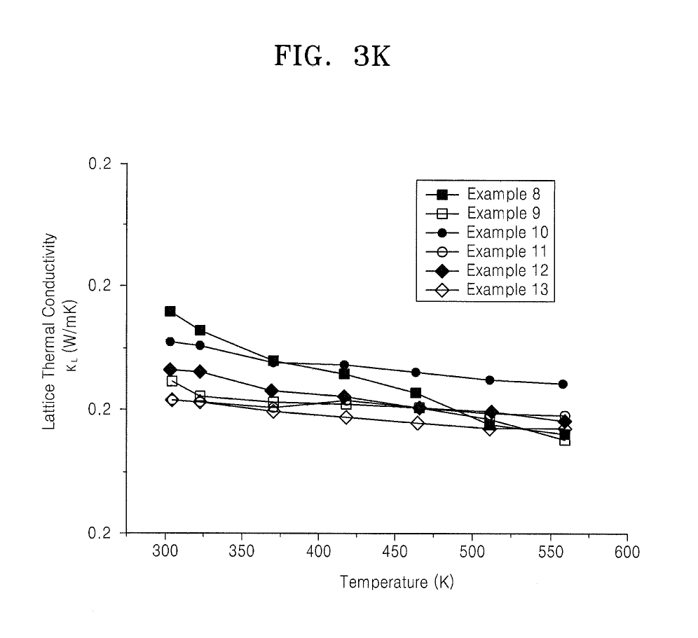

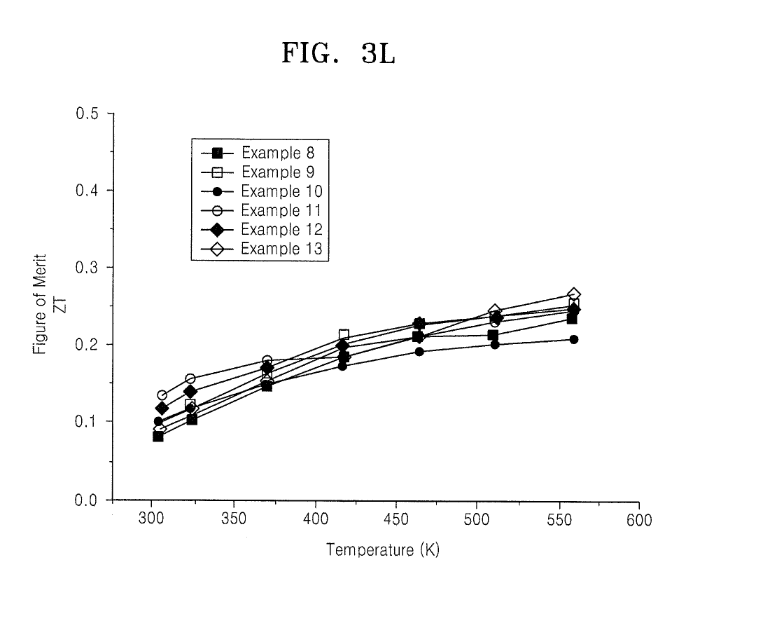

With regard to thermoelectric materials prepared according to Examples 1 to 7 and Comparative Examples 1 and 2, various physical properties were measured and calculated at 300 K to 600 K, and some of the results are shown in Table 1 and FIGS. 3A to 3F. Data in Table 1 is the result measured at 300 K. Further, with regard to thermoelectric materials prepared according to Examples 8 to 13, various physical properties were measured and calculated at 300 K to 600 K, and some of the results are shown in Table 1 and FIGS. 3G to 3L.

Using a ZEM-3 instrument (manufactured by ULVAC-RIKO company), the electrical conductivity and the Seebeck coefficient were measured at the same time, and some of the results are shown in FIGS. 3A and 3B, respectively.

The thermal conductivities were calculated based on thermal diffusivities that are measured using an ULVAC TC-9000H instrument (a Laser Flash method), and some of the results are shown in FIG. 3D. The lattice thermal conductivities were assumed and calculated based on Lorenz lattice (that is, L=2×10⁻⁸ WOhm^{K-2}), and some of the results are shown in FIG. 3E.

Some of the power factor and figure of merit ZT results that are calculated from the above results are shown in FIGS. 3C to 3F, respectively.

TABLE 1

| | Thermal | | | | |
|---|---|---|---|---|---|
| | conduc- | Lattice | Electrical | Seebeck | FIG. |
| | tivity | thermal | conductivity | coefficient | of |
| | (kₜₒₜ) | conductivity | (σ) | (S) | merit |
| | [W/mK] | (k_{L}) [W/mK] | [S/cm] | [μV/K] | (ZT) |
| Example 1 | 0.5 | 0.398 | 155 | −129 | 0.16 |
| Example 2 | 0.47 | 0.395 | 115 | −140 | 0.15 |
| Example 8 | 0.59 | 0.46 | 203 | −98 | 0.10 |
| Example 9 | 0.58 | 0.51 | 122 | −126 | 0.10 |
| Example 10 | 0.47 | 0.41 | 91 | −152 | 0.14 |
| Example 11 | 0.54 | 0.45 | 157 | −128 | 0.14 |
| Example 12 | 0.55 | 0.44 | 172 | −111 | 0.12 |
| Example 13 | 0.55 | 0.42 | 218 | −90 | 0.10 |
| Comparative | 0.6 | 0.4 | 430 | −90 | 0.14 |
| Example 1 | | | | | |
| Comparative | 0.8 | 0.5 | 550 | −85 | 0.12 |
| Example 2 | | | | | |
| Comparative | 0.85 | 0.7 | 140 | −120 | 0.08 |
| Example 3 | | | | | |
| Comparative | 1.1 | 0.75 | 222 | −83 | 0.05 |
| Example 4 | | | | | |

As shown in Table 1 and FIGS. 3A to 3F, the thermoelectric materials prepared according to Examples 1 and 2 have the lattice thermal conductivities and (total) thermal conductivities that are significantly reduced compared to the thermoelectric materials prepared according to Comparative Examples.

In addition, the thermoelectric materials prepared according to Examples 1 and 2 have the electrical conductivities and Seebeck coefficients that are similar to the thermoelectric materials prepared according to Comparative Examples 1 and 2. As a result, the thermoelectric materials prepared according to Examples 1 and 2 provide improved figures of merit.

In particular, the thermoelectric materials prepared according to Example 1 have significantly improved Seebeck coefficients compared to the thermoelectric material prepared according to Comparative Example 1

As described above, according to the one or more of the above embodiments, a compound of a new composition may improve a figure of merit of a thermoelectric material based on reduced thermal conductivity and improved electrical conductivity.

It should be understood that the exemplary embodiments described herein should be considered in a descriptive sense only and not for purposes of limitation. Descriptions of features, advantages, or aspects within each embodiment should be considered as available for other similar features or aspects in other embodiments.

What is claimed is:

1. A thermoelectric material comprising a compound represented by Formula 1:
MₓBi_{y-a}AₐSe_{z-b}Q_{b} Formula 1
wherein, 1<x<2, 4<y−a<5, 7<z−b<9, 0≦a<5, and 0≦b<9;
M is at least one transition metal element;
A is at least one element of Groups 13 to 15; and
Q is at least one element of Groups 16 or 17.

2. The thermoelectric material of claim 1, wherein the compound is represented by Formula 2:
MₓBi_{y-a}AₐSe_{z-b}Q_{b} Formula 2
wherein, 1.5<x<2, 4.5<y−a<5, 7.5<z−b<8.5, 0≦a<5, and 0≦b<8.5;
M is at least one of Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, or Hg;
A is at least one element of Groups 13 to 15; and
Q is at least one element of Groups 16 to 17.

3. The thermoelectric material of claim 1, wherein M is at least one of Cu or Ag.

4. The thermoelectric material of claim 1, wherein A is at least one of Al, Si, P, Ga, Ge, As, In, Sn, Sb, Tl, or Pb.

5. The thermoelectric material of claim 1, wherein A is at least one of Sb or Sn.

6. The thermoelectric material of claim 1, wherein Q is at least one of S, Cl, Br, Te, I, Po, or At.

7. The thermoelectric material of claim 1, wherein Q is at least one of Te or S.

8. The thermoelectric material of claim 1, wherein the compound is represented by Formula 5:
MₓBi_{y}Se_{z} Formula 5
wherein, 1.5<x<2, 4.5<y<5, and 7.5<z<8.5; and
M is at least one of Cu or Ag.

9. The thermoelectric material of claim 1, wherein the compound comprises a monoclinic crystal structure.

10. The thermoelectric material of claim 1, wherein the compound comprises a monoclinic crystal structure belonging to a C2/m space group.

11. The thermoelectric material of claim 1, wherein the compound comprises a single-crystalline structure or a polycrystalline structure.

12. The thermoelectric material of claim 1, wherein the compound comprises an electrical conductivity of 10 Siemens per centimeter or more at 300 Kelvin.

13. The thermoelectric material of claim 1, wherein the compound comprises a lattice thermal conductivity of 0.5 Watts per meter-Kelvin or less at 300 Kelvin.

14. The thermoelectric material of claim 1, wherein the compound comprises a thermal conductivity of 1 Watts per meter-Kelvin or less at 300 Kelvin.

15. The thermoelectric material of claim 1, wherein the compound comprises a Seebeck coefficient of an absolute value of 100 microvolts per Kelvin or more at 300 Kelvin.

16. The thermoelectric material of claim 1, wherein the thermoelectric material is a bulk phase.

17. The thermoelectric material of claim 1, wherein the thermoelectric material is in a form of a sinter or a powder.

18. A thermoelectric element comprising the thermoelectric material of claim 1.

19. A thermoelectric module comprising:
a first electrode;
a second electrode; and
the thermoelectric element according to claim 18 interposed between the first electrode and the second electrode.

20. A thermoelectric apparatus comprising the thermoelectric module of claim 19, wherein the thermoelectric apparatus is a thermoelectric power generator, a thermoelectric cooler, a thermoelectric sensor, a thermoelectric wireless independent power device, a power supply device for a spacecraft, or a solar power generator.
